(19) United States
(12) Patent Application Publication
(10) Pub. No.: US 2024/0273264 A1
(43) Pub. Date: Aug. 15, 2024

(54) TRAINING AND CONTROL DEVICE, TRAINING DEVICE, CONTROL DEVICE, TRAINING AND CONTROL METHOD, TRAINING METHOD, CONTROL METHOD, RECORDING MEDIUM STORING TRAINING AND CONTROL PROGRAM, RECORDING MEDIUM STORING TRAINING PROGRAM, AND RECORDING MEDIUM STORING CONTROL PROGRAM

(71) Applicant: OMRON Corporation, Kyoto-shi, Kyoto (JP)

(72) Inventors: Yoshihisa IJIRI, Kyoto-shi, Kyoto (JP); Felix VON DRIGALSKI, Tokyo (JP); Kazutoshi TANAKA, Tokyo (JP); Masashi HAMAYA, Tokyo (JP); Ryo YONETANI, Tokyo (JP)

(73) Assignee: OMRON Corporation, Kyoto-shi, Kyoto (JP)

(21) Appl. No.: 18/566,892

(22) PCT Filed: Mar. 25, 2022
(86) PCT No.: PCT/JP2022/014694

§ 371 Date: Dec. 4, 2023

(30) Foreign Application Priority Data
Jun. 30, 2021 (JP) 2021-109158

(51) Int. Cl. G06F 30/27

(52) U.S. Cl. CPC G06F 30/27

(57) ABSTRACT

A training device of a training and control device generates plural dynamics model, and trains a switching model for designating a dynamics model therefrom that corresponds to a state of a robot and a command action. A control device acquires a state of the robot generates plural candidate command series for the robot, by executing the switching model input with each command contained in each candidate command series and state corresponding to each command, designates the dynamics model applicable to each command and state corresponding to the command. For each of the candidate command series, the control device generates a predicted state series using the dynamics model designated as corresponding to the commands contained in the candidate command series, generates a predicted command series predicted to maximize a reward of the predicted state series, and outputs a first command contained in the predicted command series.

### TECHNICAL FIELD

Technology disclosed herein relates to a training and control device, a training device, a control device, a training and control method, a training method, a control method, a training and control program, a training program, and a control program.

### BACKGROUND ART

A method to perform model-based reinforcement learning employing plural state transition models is disclosed in Non-Patent Document 1.

A method disclosed in Non-Patent Document 2 divides a whole space from a training trajectory into sub-spaces having separate sub-goals, and learns a different policy (control device) for each of the divided sub-spaces.
Non-Patent Document 1: “Multiple model-based reinforcement learning” by K. Doya, K. Samejima, K. Katagiri, and M. Kawato in Neural computation, vol. 14, no. 6, pp. 1347-1369, 2002.
Non-Patent Document 2: “Learning from trajectories via subgoal discovery” by Paul, Sujoy, Jeroen van Baar, and Amit K. Roy-Chowdhury in arXiv preprint arXiv: 1911.07224 (2019).

### SUMMARY OF INVENTION

### Technical Problem

A considerable effort is involved in programing a cycle of actions to be executed by a control target such as a robot or the like, and such effort would be able to be eliminated were the cycle of actions of the control target to be learnt autonomously.

However, many attempts are required when trying to train so as to accurately predict all state transitions of a cycle of actions using a single model.

In consideration of the above circumstances, an object of technology disclosed herein is to provide a training and control device, a training device, a control device, a training and control method, a training method, a control method, a training and control program, a training program, and a control program that are capable of training a model applicable to all actions of a cycle executed by a control target using few attempts, and that are capable of controlling all actions of the cycle executed by the control target using the trained model.

### Solution to Problem

A first aspect of the present disclosure is a training and control device including a state transition data acquisition section, a dynamics model generation section, an appending section, a training section, a state acquisition section, a candidate command series generation section, a designation section, a predicted state series generation section, a computation section, a predicted command series generation section, an output section, and an execution control section. The state transition data acquisition section acquires plural state transition data obtained by causing a control target to perform a predetermined cycle of actions and configured including a state of the control target, a command action commanded of the control target at the state, and a next state after the control target has performed the command action. The dynamics model generation section generates plural dynamics models input with the state and the command action and outputting the next state, with each of the dynamics models conforming to a set of state transition data configured from some of the plural acquired state transition data, and the plural dynamics models conforming to mutually different sets of the state transition data. The appending section appends the state transition data contained in a set of the state transition data conforming to a generated dynamics model with a label to identify the conforming dynamics model. The training section uses the state transition data appended with the labels as training data to train a switching model for designating the dynamics model corresponding to the state of the control target and the command action that have been input from out of the plural dynamics models. The state acquisition section acquires a state of the control target. The candidate command series generation section generates plural candidate command series for the control target. The designation section designates the dynamics model applicable to each command and state corresponding to the command by executing the switching model input with each command contained in a candidate command series and with a state corresponding to each of the commands. The predicted state series generation section, for each of the candidate command series, uses the dynamics model designated as corresponding to the respective commands contained in the candidate command series to generate a predicted state series. The computation section computes a reward for each predicted state series. The predicted command series generation section generates a predicted command series predicted to maximize the reward. The output section outputs a first command contained in the generated predicted command series. The execution control section controls action of the control target by repeating a cycle of actions of the state acquisition section, the candidate command series generation section, the designation section, the predicted state series generation section, the computation section, the predicted command series generation section, and the output section.

The first aspect described above may be configured such that, when each generating a single dynamics model from out of the plural dynamics models, the dynamics model generation section generates a candidate for the dynamics model using all of the state transition data usable for generating this dynamics model, and after this computes an error between the next state obtained when the state of the control target and the command action are input to the generated candidate dynamics model and the next state contained in the state transition data including this state and this command action. The dynamics model generation section then generates the dynamics model such that the computed error is a predetermined threshold or lower by repeatedly generating the candidate dynamics model while removing the state transition data for which the error is a maximum.

The first aspect described above may be configured such that, for each generating of a single dynamics model from out of the plural dynamics models, the dynamics model generation section treats the state transition data that remained not removed in a process to generate this dynamics model as being unusable for subsequent generating of the dynamics model, and generates a next of the dynamics models.

The first aspect described above may be configured such that at a predetermined frequency the dynamics model generation section takes the state transition data selected at random from out of the state transition data removed as having the maximum error and returns this state transition data to the state transition data employed for generating the dynamics model, and then generates the dynamics model.

The first aspect described above may be configured such that the candidate command series generation section generates a single candidate for the command series, the predicted state series generation section generates the predicted state series corresponding to the candidate command series generated by the candidate command series generation section, the computation section computes a reward of the predicted state series generated by the predicted state series generation section, and the predicted command series generation section generates a predicted command series for which the reward is predicted to be maximized by performing updating one or more times of the candidate command series such that the reward increases by causing a cycle of actions of the candidate command series generation section, the designation section, the predicted state series generation section, and the computation section to be executed plural times.

The first aspect described above may be configured such that the candidate command series generation section generates a batch of plural candidates of the command series, the predicted state series generation section generates the predicted state series from each of the plural candidate command series, the computation section computes a reward for each of the predicted state series, and the predicted command series generation section generates a predicted command series predicted to maximize the reward based on the reward for each of the predicted state series.

The first aspect described above may be configured such that the candidate command series generation section causes processing of a cycle from processing for batch-generating the plural candidate command series until processing to compute the reward to be executed repeatedly plural times, and in processing of the cycle from the second time onward, the candidate command series generation section selects the plural candidate command series corresponding to predetermined upper rank rewards from out of rewards computed in processing of the previous cycle, and generates new plural candidates of the command series based on a distribution of the selected plural candidate command series.

A second aspect of the present disclosure is a training device including a state transition data acquisition section, a dynamics model generation section, an appending section, and a training section. The state transition data acquisition section acquires plural state transition data obtained by causing a control target to perform a predetermined cycle of actions and configured including a state of the control target, a command action commanded of the control target at the state, and a next state after the control target has performed the command action. The dynamics model generation section generates plural dynamics models input with the state and the command action and outputting the next state, with each of the dynamics models conforming to a set of state transition data configured from some of the plural acquired state transition data, and the plural dynamics models conforming to mutually different sets of the state transition data. The appending section appends the state transition data contained in a set of the state transition data conforming to a generated dynamics model with a label to identify the conforming dynamics model. The training section uses the state transition data appended with the labels as training data to train a switching model for designating the dynamics model corresponding to the state of the control target and the command action that have been input from out of the plural dynamics models.

A third aspect of the present disclosure is a control device including a state acquisition section, a candidate command series generation section, a designation section, a predicted state series generation section, a computation section, a predicted command series generation section, an output section, and an execution control section. The state acquisition section acquires a state of the control target. The candidate command series generation section generates plural candidate command series for the control target. The designation section, by executing the switching model that is input with each command contained in each candidate command series and with a state corresponding to each of the commands and that has been trained by the training device, designates the dynamics model that is applicable to each command and state corresponding to the command from out of the dynamics models generated by the training device. The predicted state series generation section, for each of the candidate command series, uses the dynamics model designated as corresponding to the respective commands contained in the candidate command series to generate a predicted state series. The computation section computes a reward for each predicted state series. The predicted command series generation section generates a predicted command series predicted to maximize the reward. The output section outputs a first command contained in the generated predicted command series. The execution control section controls action of the control target by repeating a cycle of actions of the state acquisition section, the candidate command series generation section, the designation section, the predicted state series generation section, the computation section, the predicted command series generation section, and the output section.

A fourth aspect of the present disclosure is a training and control method of processing executed by a computer. The processing includes: a state transition data acquisition step that acquires plural state transition data obtained by causing a control target to perform a predetermined cycle of actions and configured including a state of the control target, a command action commanded of the control target at the state, and a next state after the control target has performed the command action; a dynamics model generation step that generates plural dynamics models input with the state and the command action and outputting the next state, with each of the dynamics models conforming to a set of state transition data configured from some of the plural acquired state transition data, and the plural dynamics models conforming to mutually different sets of the state transition data; an appending step that appends the state transition data contained in a set of the state transition data conforming to a generated dynamics model with a label to identify the conforming dynamics model; a training step that uses the state transition data appended with the labels as training data to train a switching model for designating the dynamics model from out of the plural dynamics models that corresponds to the state of the control target and the command action that have been input; a state acquisition step that acquires a state of the control target; a candidate command series generation step that generates plural candidate command series for the control target; a designation step that designates the dynamics model applicable to each command and state corresponding to the command by executing the switching model input with each command contained in a candidate command series and with a state corresponding to each of the commands; a predicted state series generation step that, for each of the candidate command series, uses the dynamics model designated as corresponding to the respective commands contained in the candidate command series to generate a predicted state series; a computation step that computes a reward for each predicted state series; a predicted command series generation step that generates a predicted command series predicted to maximize the reward; an output step that outputs a first command contained in the generated predicted command series; and an execution control step that controls action of the control target by repeating a cycle of actions of the state acquisition step, the candidate command series generation step, the designation step, the predicted state series generation step, the computation step, the predicted command series generation step, and the output step.

A fifth aspect of the present disclosure is a training method of processing executed by a computer. The processing includes: a state transition data acquisition step that acquires plural state transition data obtained by causing a control target to perform a predetermined cycle of actions and configured including a state of the control target, a command action commanded of the control target at the state, and a next state after the control target has performed the command action; a dynamics model generation step that generates plural dynamics models input with the state and the command action and outputting the next state, with each of the dynamics models conforming to a set of state transition data configured from some of the plural acquired state transition data, and the plural dynamics models conforming to mutually different sets of the state transition data; an appending step that appends the state transition data contained in a set of the state transition data conforming to a generated dynamics model with a label to identify the conforming dynamics model; and a training step that uses the state transition data appended with the labels as training data to train a switching model for designating the dynamics model from out of the plural dynamics models that corresponds to the state of the control target and the command action that have been input.

A sixth aspect of the present disclosure is a control method of processing executed by a computer. The processing includes: a state acquisition step that acquires a state of the control target; a candidate command series generation step that generates plural candidate command series for the control target; a designation step that, by executing a switching model that is input with each command contained in each candidate command series and with a state corresponding to each of the commands and that has been trained by the training method, designates the dynamics model applicable to each command and state corresponding to the command from out of the dynamics models generated by the training method; a predicted state series generation step that, for each of the candidate command series, uses the dynamics model designated as corresponding to the respective commands contained in the candidate command series to generate a predicted state series; a computation step that computes a reward for each predicted state series; a predicted command series generation step that generates a predicted command series predicted to maximize the reward; an output step that outputs a first command contained in the generated predicted command series; and an execution control step that controls action of the control target by repeating a cycle of actions of the state acquisition step, the candidate command series generation step, the designation step, the predicted state series generation step, the computation step, the predicted command series generation step, and the output step.

A seventh aspect of the present disclosure is a training and control program that causes a computer to execute processing. The processing includes: a state transition data acquisition step that acquires plural state transition data obtained by causing a control target to perform a predetermined cycle of actions and configured including a state of the control target, a command action commanded of the control target at the state, and a next state after the control target has performed the command action; a dynamics model generation step that generates plural dynamics models input with the state and the command action and outputting the next state, with each of the dynamics models conforming to a set of state transition data configured from some of the plural acquired state transition data, and the plural dynamics models conforming to mutually different sets of the state transition data; an appending step that appends the state transition data contained in a set of the state transition data conforming to a generated dynamics model with a label to identify the conforming dynamics model; a training step that uses the state transition data appended with the labels as training data to train a switching model for designating the dynamics model from out of the plural dynamics models that corresponds to the state of the control target and the command action that have been input; a state acquisition step that acquires a state of the control target; a candidate command series generation step that generates plural candidate command series for the control target; a designation step that designates the dynamics model applicable to each command and state corresponding to the command by executing the switching model input with each command contained in a candidate command series and with a state corresponding to each of the commands; a predicted state series generation step that, for each of the candidate command series, uses the dynamics model designated as corresponding to the respective commands contained in the candidate command series to generate a predicted state series; a computation step that computes a reward for each predicted state series; a predicted command series generation step that generates a predicted command series predicted to maximize the reward; an output step that outputs a first command contained in the generated predicted command series; and an execution control step that controls action of the control target by repeating a cycle of actions of the state acquisition step, the candidate command series generation step, the designation step, the predicted state series generation step, the computation step, the predicted command series generation step, and the output step.

An eighth aspect of the present disclosure is a training program that causes a computer to execute processing. The processing includes: a state transition data acquisition step that acquires plural state transition data obtained by causing a control target to perform a predetermined cycle of actions and configured including a state of the control target, a command action commanded of the control target at the state, and a next state after the control target has performed the command action; a dynamics model generation step that generates plural dynamics models input with the state and the command action and outputting the next state, with each of the dynamics models conforming to a set of state transition data configured from some of the plural acquired state transition data, and the plural dynamics models conforming to mutually different sets of the state transition data; an appending step that appends the state transition data contained in a set of the state transition data conforming to a generated dynamics model with a label to identify the conforming dynamics model; and a training step that uses the state transition data appended with the labels as training data to train a switching model for designating the dynamics model from out of the plural dynamics models that corresponds to the state of the control target and the command action that have been input.

A ninth aspect of the present disclosure is control program that causes a computer to execute processing. The processing includes: a state acquisition step that acquires a state of the control target; a candidate command series generation step that generates plural candidate command series for the control target; a designation step that, by executing a switching model that is input with each command contained in each candidate command series and with a state corresponding to each of the commands and that has been trained by the training program, designates the dynamics model applicable to each command and state corresponding to the command from out of the dynamics models generated by the training program; a predicted state series generation step that, for each of the candidate command series, uses the dynamics model designated as corresponding to the respective commands contained in the candidate command series to generate a predicted state series; a computation step that computes a reward for each predicted state series; a predicted command series generation step that generates a predicted command series predicted to maximize the reward; an output step that outputs a first command contained in the generated predicted command series; and an execution control step that controls action of the control target by repeating a cycle of actions of the state acquisition step, the candidate command series generation step, the designation step, the predicted state series generation step, the computation step, the predicted command series generation step, and the output step.

The present disclosure enables a model applicable to all actions of a cycle executed by a control target to by trained by few attempts and also enables all actions of the cycle executed by the control target to be controlled using a trained model.

### BRIEF DESCRIPTION OF DRAWINGS

FIG. 1 is a configuration diagram of a robot system.

FIG. 2 is a diagram illustrating the schematic configuration of a robot.

FIG. 3 is a diagram illustrating a cycle of actions executed by a robot.

FIG. 4 is a block diagram illustrating a hardware configuration of a training and control device.

FIG. 5 is a diagram illustrating a functional configuration of a training device.

FIG. 6 is a diagram illustrating a functional configuration of a control device.

FIG. 7 is a flowchart of training processing.

FIG. 8 is a flowchart illustrating model generation processing.

FIG. 9 is a flowchart of control processing 1.

FIG. 10 is a flowchart of control processing 2.

### DESCRIPTION OF EMBODIMENTS

Description follows regarding an example of exemplary embodiments of the present disclosure, with reference to the drawings. Note that the same reference numerals will be appended in each of the drawings to configuration elements and portions that are either the same or equivalent. Moreover for ease of explanation, sometimes the dimensional proportions are exaggerated in the drawings and differ from actual dimensional proportions.

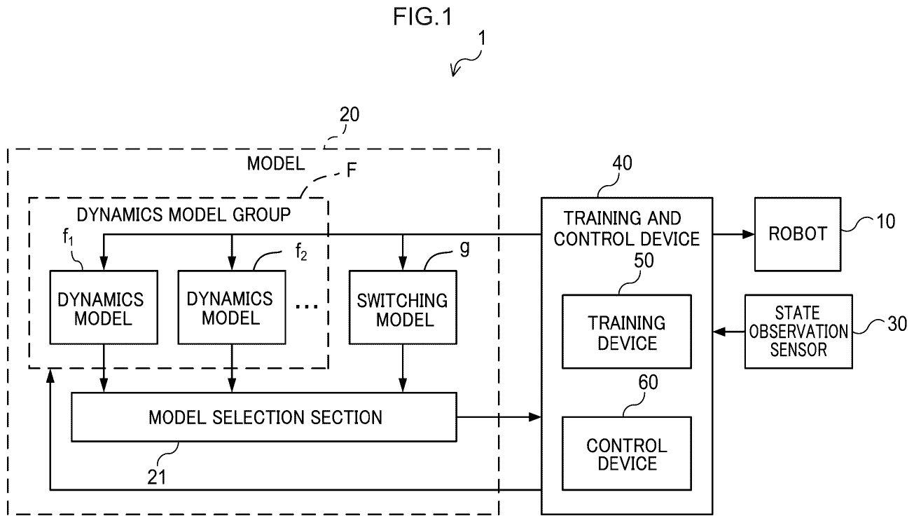

FIG. 1 illustrates a configuration of a robot system 1. The robot system 1 includes a robot 10 serving as an example of a control target, a model 20, a state observation sensor 30, and a training and control device 40.

### Robot

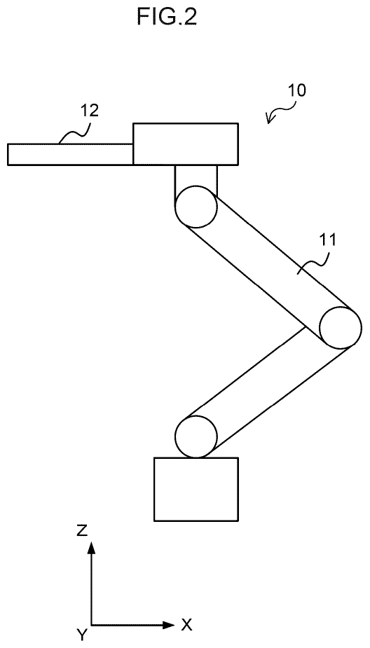

FIG. 2. is a diagram illustrating a schematic configuration of the robot 10 serving as an example of a control target. The robot 10 of the present exemplary embodiment is an upright, six-axis, multi-jointed robot including an arm 11 having six degrees of freedom. A flat plate shaped hand 12 is installed at the leading end of the arm 11.

Note that the robot 10 is not limited to being an upright multi-jointed robot, and may be a horizontal multi-jointed robot (SCARA robot). Moreover, although an example has been given of a six-axis robot, the robot may be a multi-jointed robot having other degrees of freedom, such as a five-axis or seven-axis robot, or the like, or may be a parallel-link robot.

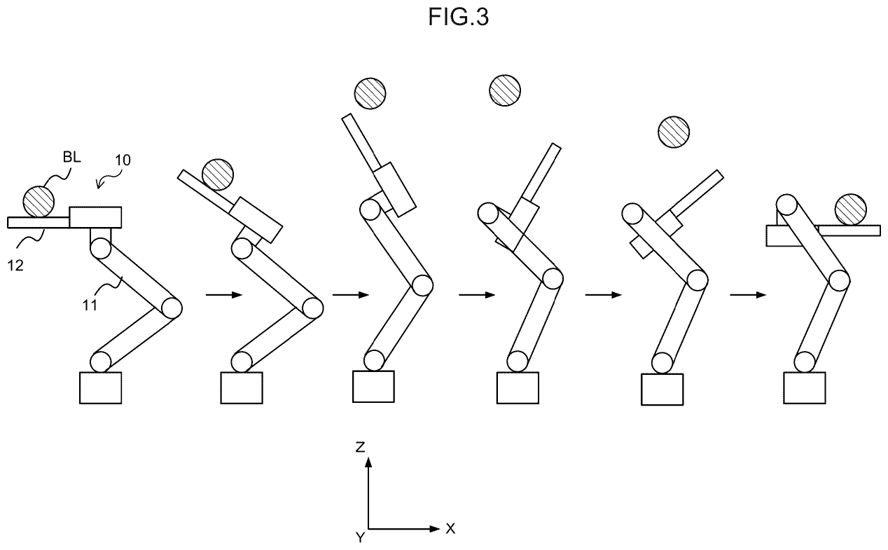

In the present exemplary embodiment, as a cycle of actions as illustrated in FIG. 3, the robot 10 executes a juggling action with a state of a ball BL resting on a front face of the hand 12 is an initial state, the ball BL being thrown upward in FIG. 3 and the hand 12 reversed, and the ball BL then resting on the back face of the hand 12. Namely, in cases in which the hand 12 is thought of as being a human hand, then the cycle of actions executed by the robot 10 is a juggling action from a state in which the ball BL is resting on the palm of a horizontal hand, the ball BL being thrown upward and the hand is reversed, with the ball BL then resting on the back of the horizontal hand.

### Model

The model 20 includes a dynamics model group F, a switching model g, and a model selection section 21. The dynamics model group F includes plural dynamics models f₁, f₂, . . . . Note that these will be referred to as dynamics model f when no discrimination is made between each of these dynamics models.

The dynamics models f are models that are input with a state sₜ of the robot 10 and a command action aₜ commanded of the robot 10 at the state sₜ, and that output a next state sₜ₊₁ after the robot 10 has performed the command action aₜ.

The switching model g designates a dynamics model f corresponding to the input state sₜ and the command action at of the robot 10 from out of plural dynamics models f.

The model selection section 21 selects the dynamics model f designated by the switching model g, and takes the next state sₜ₊₁ output from the selected dynamics model f and outputs this to the training and control device 40.

The robot system 1 employs machine learning (for example, model-based reinforcement learning) to acquire the switching model g for selecting the dynamics model f to perform control of the robot 10 as described above.

### State Observation Sensor

The state observation sensor 30 observes states of the robot 10 and the ball BL, and outputs observed data as state observation data. The state observation sensor 30, for example, includes an encoder in a joint of the robot 10. A position and orientation of the hand 12 at the leading end of the arm 11 can be designated as the state of the robot 10 from the angle of each joint. Moreover, for example, the state observation sensor 30 also includes a camera for imaging the ball BL. The position of the ball BL can be designated based on an image imaged by the camera.

### Training and Control Device

As illustrated in FIG. 1, the training and control device 40 includes a training device 50 and a control device 60.

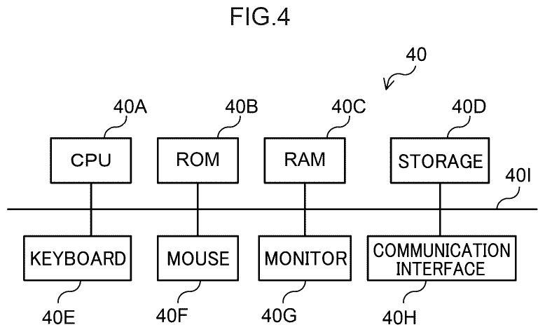

FIG. 4 is a block diagram illustrating a hardware configuration of the training and control device 40 according to the present exemplary embodiment. As illustrated in FIG. 4, the training and control device 40 has a configuration similar to that of a general purpose computer (information processing device), and includes a central processing unit (CPU) 40A, read only memory (ROM) 40B, random access memory (RAM) 40C, storage 40D, a keyboard 40E, a mouse 40F, a monitor 40G, and a communication interface 40H. Each configuration is connected so as to be capable of communicating with each other through a bus 40I.

In the present exemplary embodiment, a training program for executing processing to train a model and a control program for controlling the robot 10 are stored on the ROM 40B or the storage 40D. The CPU 40A is a central processing unit that executes various programs and controls each configuration. Namely, the CPU 40A reads programs from the ROM 40B or the storage 40D and executes the programs using the RAM 40C as a workspace. The CPU 40A controls each of the configuration and performs various computations according to the programs recorded on the ROM 40B or the storage 40D. The ROM 40B stores various programs and various data. The RAM 40C is employed as workspace to temporarily store programs or data. The storage 40D is configured by a hard disk drive (HDD), solid state drive (SSD), flash memory, or the like, and stores various programs including an operating system and various data. The keyboard 40E and the mouse 40F are examples of input devices, and are employed to perform various input. The monitor 40G is, for example, a liquid crystal display and displays a user interface. A touch panel may be employed for the monitor 40G and function also as an input section. The communication interface 40H is an interface for communication with other devices and employs, for example, a standard such as Ethernet (registered trademark), FDDI, Wi-Fi (registered trademark), or the like.

Next, description follows regarding a functional configuration of the training device 50.

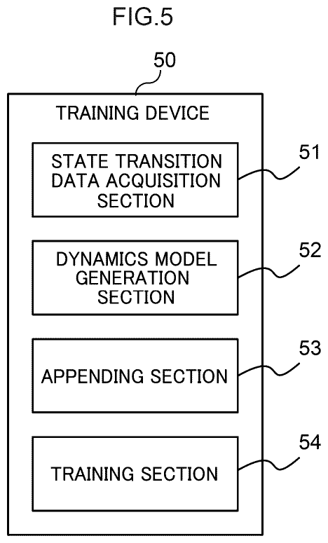

As illustrated in FIG. 5, the training device 50 includes, as functional configuration, a state transition data acquisition section 51, a dynamics model generation section 52, an appending section 53, and a training section 54. Each of the functional configurations is implemented by the CPU 40A reading the training program stored on the ROM 40B or the storage 40D, and expanding and executing the training program in the RAM 40C. Note that part or all of these functions may be implemented by a dedicated hardware device.

As state transition data, the state transition data acquisition section 51 acquires plural tuples obtained by causing a predetermined cycle of actions to be performed by the robot 10 and configured by a state sₜ of the robot 10, a command action at commanded of the robot 10 at state sₜ, and a next state sₜ₊₁ after the robot 10 has performed the command action.

The dynamics model generation section 52 generates plural dynamics models f that are input with the state sₜ and the command action at and that output the next state sₜ₊₁. Each of the dynamics models f conforms to a tuple set configured from some of the plural acquired tuples, and the plural dynamics models f conform to mutually different tuple sets.

Moreover, when generating a single dynamics model f from out of plural dynamics models f, the dynamics model generation section 52 generates a candidate for the dynamics model f using all the tuples usable for generating this dynamics model f. The dynamics model generation section 52 then computes an error between the next state sₜ₊₁ obtained by inputting the state sₜ of the robot 10 and the command action at into the generated candidate dynamics model f, and the next state sₜ₊₁ contained in tuples that contain the state sₜ and the command action at. The dynamics model generation section 52 generates a dynamics model f such that the computed error is a predetermined threshold or lower by repeatedly generating the candidate dynamics model f while removing the tuple for which the error is a maximum.

Moreover, each time a single dynamics model f from out of the plural dynamics models f is generated, the dynamics model generation section 52 takes the tuples that remain not excluded in the generation process of this dynamics model f as being unusable to generate subsequent dynamics models f, and generates the next dynamics model f.

Moreover, the dynamics model generation section 52 generates a dynamics model f by, at a predetermined frequency, taking a tuple selected at random from out of the tuples excluded as having the maximum error and returns this to the tuples employed for generating the dynamics model f.

The appending section 53 appends the tuples contained in the tuple set conforming to the generated dynamics model f with a label that identifies the conforming dynamics model f.

The training section 54 uses the tuples appended with labels as training data, and trains the switching model g for designating the dynamics model f corresponding to the input state sₜ and command action at of the robot 10 from out of the plural dynamics models f.

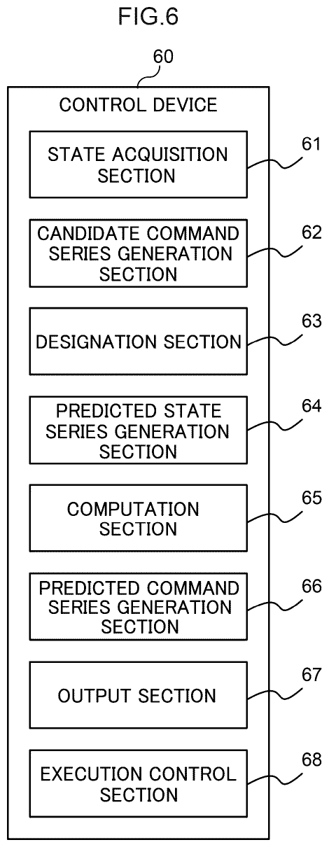

As illustrated in FIG. 6, the control device 60 includes, as functional configuration, a state acquisition section 61, a candidate command series generation section 62, a designation section 63, a predicted state series generation section 64, a computation section 65, a predicted command series generation section 66, an output section 67, and an execution control section 68. Each functional configuration is implemented by the CPU 40A reading the control program stored on the ROM 40B or the storage 40D, and expanding and executing the control program in the RAM 40C. Note that part or all of these functions may be implemented by a dedicated hardware device.

The state acquisition section 61 acquires the state sₜ of the robot 10.

The candidate command series generation section 62 generates plural candidate command series for the robot 10.

The designation section 63 designates the dynamics model f applicable to a command and a state corresponding to the command by executing the switching model g input with each command contained in a candidate command series and with a state corresponding to each of the commands.

For each of the candidate command series, the predicted state series generation section 64 generates a predicted state series using the designated dynamics model f corresponding to the respective commands contained in the candidate command series.

The computation section 65 computes a reward for each of the predicted state series.

The predicted command series generation section 66 generates a predicted command series predicted to maximize the reward.

The candidate command series generation section 62 generates a single candidate command series, the predicted state series generation section 64 generates a predicted state series corresponding to the candidate command series generated by the candidate command series generation section 62, the computation section 65 computes the reward of the predicted state series generated by the predicted state series generation section 64, the predicted command series generation section 66 generates a command series predicted to maximize the reward by updating the candidate command series one or more times so as to maximize the reward by executing the cycle of actions of the candidate command series generation section 62, the designation section 63, the predicted state series generation section 64, and the computation section 65 plural times.

A configuration may be adopted in which the candidate command series generation section 62 generates a batch of plural of the candidate command series, the predicted state series generation section 64 generates a reward predicted state series from each of the plural candidate command series, the computation section 65 computes the respective rewards for each of the predicted state series, and the predicted command series generation section 66 generates the command series predicted to maximize the reward based on the rewards for each of the predicted state series.

In such cases, a configuration may be adopted in which the candidate command series generation section 62 repeatedly executes a cycle of processing from the processing to generate the batch of plural candidate command series to the processing for computing the rewards by execution plural times, and for the processing of the second cycle onwards, the candidate command series generation section 62 selects plural candidate command series corresponding to predetermined upper rank rewards from out of the rewards computed in the previous cycle of processing, and generates plural new candidate command series based on a distribution of the plural selected candidate command series.

The output section 67 outputs the first command contained in the generated predicted command series.

The execution control section 68 controls the action of the robot 10 by repeating the cycle of actions of the state acquisition section 61, the candidate command series generation section 62, the designation section 63, the predicted state series generation section 64, the computation section 65, the predicted command series generation section 66, and the output section 67.

### Training Processing

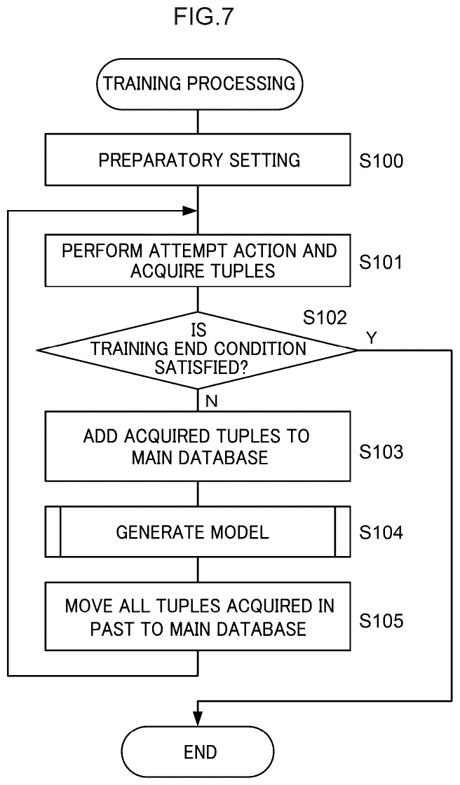

FIG. 7 is a flowchart illustrating a flow of training processing executed by the training device 50 using machine learning.

At step S100 the training device 50 performs preparatory setting. More specifically, a target state of the robot 10 is set. The cycle of actions executed by the robot 10 in the present exemplary embodiment is the juggling action, and so the target state is a state in which, after the ball BL has been thrown upward and the hand 12 reversed, the ball BL rests on a prescribed central portion of the back face of the hand 12 when the hand 12 has been made horizontal. The target state can be defined by the position and orientation of the hand 12, and by the relative position of the hand 12 and the ball BL.

Note that in cases in which the cycle of actions executed by the robot 10 is an action to grip a peg and insert it into a hole, and the hand 12 is a gripper for gripping pegs, and the target state is a state in which a peg has been inserted into a hole. In such cases the target state can be determined by the position and orientation of the peg and the gripper.

Moreover, a state partway toward the target state may be specified as the target state. In such cases, an intermediate target to define a partway state, part of a target trajectory, part of a target path, a reward computation method, and the like may be set.

Moreover, a certain extent of structure for the dynamics model f may be given. In the present exemplary embodiment the dynamics model f employs a model configured by combining a model of the hand 12 and a model of the ball BL as the dynamics model f. For example, the model of the hand 12 is a neural network, and a model of the ball BL is a linear function.

At step S101, the training device 50 executes an attempt action, and acquires plural tuples. Namely, the juggling action described above is executed by the robot 10, and plural of tuples partway through the juggling action are acquired. More specifically, a command action at is commanded of the robot 10 at state sₜ, and the state observation data observed by the state observation sensor 30 after the robot 10 has performed the command action is taken as the next state sₜ₊₁. Next, the next state sₜ₊₁ is employed as the state sₜ, and the command action at is commanded of the robot 10, and the state observation data observed by the state observation sensor 30 after the robot 10 has performed this command action is taken as the next state sₜ₊₁. The attempt action of the juggling action is executed by repeating the above, and plural tuples partway through the juggling action are acquired.

At step S102, the training device 50 determines whether or not a predetermined training end condition has been satisfied. This training end condition is a condition that enables determination that the cycle of actions by the robot 10 has been well trained and, for example, may be when the attempt action has been performed a defined number of times. Moreover, the training end condition may be taken as being when the number of times the target state has been achieved, namely the number of times that the attempt action has succeeded, has reached a defined number of times. Moreover, the training end condition may be when the time until achieving the target state is a defined time or less. Moreover, the training end condition may be when a success rate of attempt actions for each determined number of times has reached a defined value or greater.

The current routine is ended when the training end condition has been satisfied, and processing transitions to step S103 when the training end condition is not satisfied.

At step S103, the training device 50 adds the tuples acquired at step S101 to a main database. Note that the main database is a concept expressing a storage region where the acquired tuples are stored.

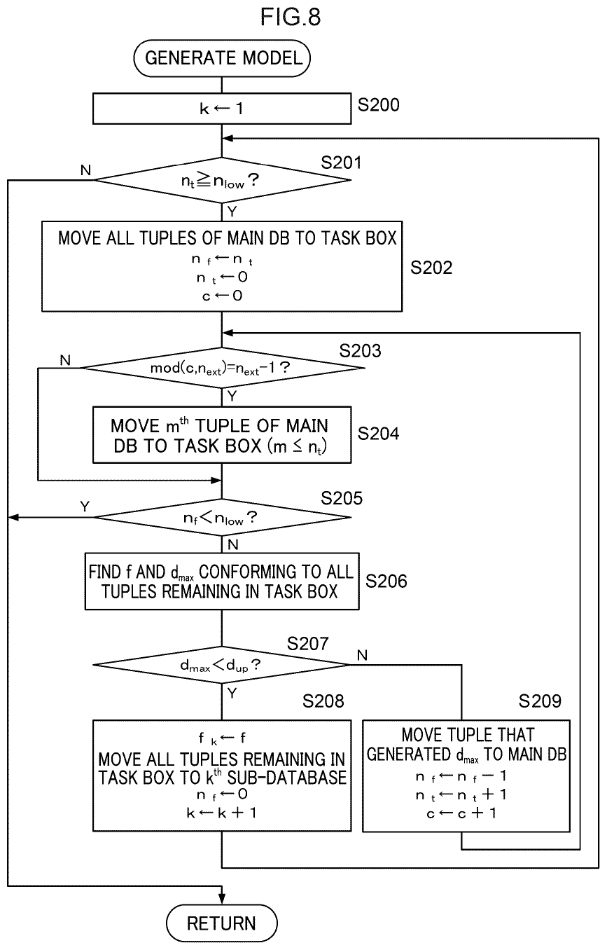

At step S104, the model generation processing illustrated in FIG. 8 is executed.

As illustrated in FIG. 8, at step S200 the training device 50 substitutes “1” for k that expresses a number of the generated dynamics models f and that serves as a label to designate the dynamics model f, and performs initialization.

At step S201, the training device 50 determines whether or not an nₜ that is a number of the tuples stored in the main database has become at least n_{low}, this being a lower limit number of tuples required to create a single dynamics model f. Processing transitions to step S202 in cases in which the nₜ is at least the n_{low}. However, the current routine is ended when the ni is less than the now, and processing transitions to step S105 of FIG. 7.

At step S202, the training device 50 moves all the tuples in the main database to a task box. Note that a task box is a concept expressing a storage region where tuples for use in generating a dynamics model f are stored.

Moreover, at step S202, nₜ is substituted for n_{f} that is a number of tuples stored in the task box. Initialization is performed by substituting “0” as nₜ. Initialization is performed by substituting 0 for a count c.

At step S203, the training device 50 determines whether or not MOD (c, nₑₓₜ), this being a remainder when the value of the count c is divided by a divisor nₑₓₜ, is equivalent to nₑₓₜ−1. Processing transitions to step S204 when MOD (c, nₑₓₜ) is equivalent to nₑₓₜ−1, and processing transitions to step S205 when MOD (c, nₑₓₜ) is not equivalent to nₑₓₜ−1. Namely, the processing of step S204 is executed at a predetermined frequency according to the divisor nₑₓₜ. The divisor nₑₓₜ is pre-set according to a frequency desired for executing the processing of step S204.

At step S204, the training device 50 moves an m^{th} tuple present in the main database into the task box. Note that m≤nₜ. m is set randomly. Namely, the tuple to be moved from the main database to the task box is selected at random. The tuples present in the main database are tuples generated with a maximum prediction error dₘₐₓ at step S209, described later, and are tuples there has been removed during the process to generate the dynamics model f. This means that at a predetermined frequency a tuple that has been generated with the maximum prediction error dₘₐₓ at step S209 described later is employed to generate the dynamics models f. The dynamics model f that is generated is accordingly able to avoid being a local optimum dynamics model f.

At step S205, the training device 50 determines whether or not the number n_{f} of the tuples stored in the task box is less than the now that is the lower limit number of tuples required for creating a single dynamics model f. The current routine is then ended when the n_{f} is less than n_{low} because a dynamics model f is unable to be created, and processing transitions to step S105 of FIG. 7. However, processing transitions to step S206 when the n_{f} is at least the now because a dynamics model f can be created.

At step S206, the training device 50 generates the dynamics model f conforming to a set of tuples stored in the task box. In the present exemplary embodiment, the dynamics model f is, as an example, a linear function, and may be found using, for example, a least squares method or the like. Note that the dynamics model f is not limited to being a linear function. For example, the dynamics model f may be generated using another linear approximation or non-linear approximation method such as a neural network, a Gaussian mixture regression (GMR), a Gaussian process regression (GPR), support vector regression, or the like.

At step S206, the training device 50 computes a maximum prediction error dₘₐₓ of the generated dynamics model f. First, errors di (i=1, 2, . . . , nr) are computed for all the tuples in the task box using the following equation.

$${d}_{i} = {‖ {s}_{t + 1} - f ( {s}_{t} , {a}_{t} ) ‖}^{2}$$

Then the error di that is the maximum from out of the computed errors di is taken as a maximum error dₘₐₓ.

At step S207, the training device 50 determines whether or not the maximum error dₘₐₓ computed at step S206 is less than a predetermined threshold dup. Processing transitions to step S208 when the maximum error dₘₐₓ is less than the threshold dup, and processing transitions to step S209 when the maximum error dₘₐₓ is the threshold dup or greater.

At step S208, the training device 50 takes the dynamics model f generated at step S206 as the k^{th} dynamics model fₖ (k=1, 2, . . . ). Note that as stated above, k is a label to identify the dynamics model f.

Moreover, the training device 50 moves all of the tuples stored in the task box to the k^{th} sub-database at step S208. In other words, the label k is appended to all the stored tuples. Sub-database is a concept of a storage region for storing tuples conforming to the generated dynamics model fₖ. The task box becomes empty due to the above, and initialization is performed by substituting “0” for the n_{f}. Moreover, k is incremented. Namely, k←k+1. The processing then transitions to step S201.

At step S209, the training device 50 moves the tuple that generated the maximum error dₘₐₓ found at step S206 into the main database. The tuples in the task box are accordingly reduced by one, and so the nris decremented. Namely, nr←n_{f}−1. Moreover, the tuples in the main database are increased by one, and so the nris incremented. Namely, nₜ←nₜ+1. Moreover, the count c is incremented. Namely, c←c+1. Then processing transitions to step S203.

In this manner the dynamics model f is generated by the remaining tuples not removed at step S209, however due to the tuples employed to generate this dynamics model f being moved to the k^{th} sub-database, these tuples are treated as being unusable for generation of the next k+1^{th} dynamics model f.

Processing transitions to step S105 of FIG. 7 when negative determination is made at step S201 and affirmative determination is made at step S205.

At step S105 of FIG. 7, the training device 50 moves all the tuples acquired in the past at step S101 to the main database.

Thus the generated dynamics model fₖ is discarded each time an attempt action is performed, and all the tuples acquired in the past are moved to the main database, and training performed again. Plural dynamics model f are accordingly generated automatically thereby until the training end condition has been satisfied.

Hitherto there has been a need to perform many attempts when trying to perform training so as to accurately predict all the state transitions of the cycle of actions to be executed by the robot 10 using a single model. However, the present exemplary embodiment enables training of a model capable of being applied to all actions of the cycle to be executed by the robot 10 using a few attempts.

### Control Processing 1

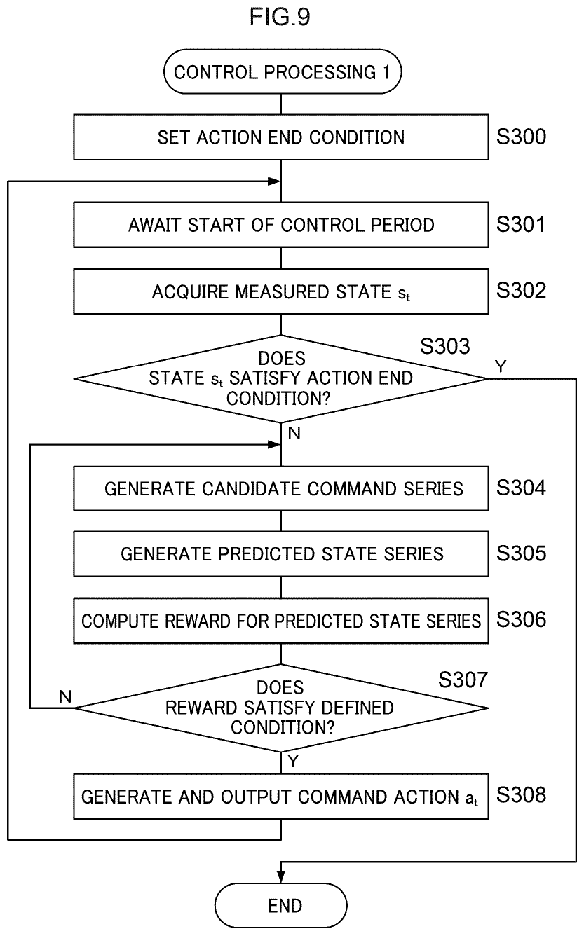

FIG. 9 is a flowchart illustrating a flow of control processing 1 executed by the control device 60.

At step S300, an action end condition is set for the robot 10. The action end condition is, for example, when a difference between the state sₜ and a target state is within a defined value.

The processing of step S301 to S308 described below is executed at a fixed time interval according to a control period. The control period is set to a time that enables the processing of step S301 to step S308 to be executed.

At step S301, the control device 60 adopts standby until a prescribed period of time equivalent a length of the control period has elapsed from when the control period was started the previous time.

At step S302, the control device 60 acquires the state si of the robot 10. Namely, state observation data of the robot 10 is acquired from the state observation sensor 30. More specifically, the state sₜ is, for example, positions of the robot 10 (the hand 12) and of a manipulation target object (the ball BL). Note that a speed is found from a position in the past and a current position.

At step S303, the control device 60 determines whether or not the state sₜ acquired at step S302 satisfies the action end condition set at step S300. The current routine is ended when the state sₜ satisfies the action end condition. However, processing transitions to step S304 when the state sₜ has not satisfied the action end condition.

At step S304, the control device 60 generates a candidate command series for the robot 10. In the present exemplary embodiment, a number of time series steps is three (t, t+1, t+2), and a candidate command series aₜ, aₜ₊₁, aₜ₊₂ is generated that corresponds to the state sₜ of the robot 10 measured at step S302. Note that the number of time series steps is not limited to being three, and may be freely set. Note that the candidate command series aₜ, aₜ₊₁, aₜ₊₂ is generated at random by processing during the first lap. For the processing of the second lap onward a Newton's method may, for example, be employed to update the candidate command series aₜ, aₜ₊₁, aₜ₊₂ such that reward increases.

At step S305, the control device 60 generates a predicted state series of the robot 10. Namely, a predicted state series is generated using the designated dynamics model f corresponding to the candidate command series aₜ, aₜ₊₁, aₜ₊₂ generated at step S304.

More specifically, the state sₜ and command action atare input to the plural dynamics models f and to the switching model g, the next state sₜ₊₁ is acquired as output from the dynamics model fₖ employing the state sₜ and the command action at and designated by the switching model g. Note that a configuration may be adopted in which the state sₜ and the command at are input only to the switching model g, the state sₜ and the command action at are then input only to the dynamics model fₖ employing the state sₜ and the command action at and designated by the switching model g, and the next state sₜ₊₁ acquired therefrom. Similar applies to the following processing.

Next, the state sₜ₊₁ and the command aₜ₊₁ are input to the plural dynamics models f and to the switching model g, and a next state sₜ₊₂ is acquired as output from the dynamics model fₖ employing the state sₜ₊₁ and the command aₜ₊₁ and designated by the switching model g.

Next, the state sₜ₊₂ and the command aₜ₊₂ are input to the plural dynamics models f and the switching model g, and a next state sₜ₊₃ is acquired as output from the dynamics model fₖ employing the state sₜ₊₂ and the command aₜ₊₂ and designated by the switching model g. The predicted state series sₜ₊₁, sₜ₊₂, sₜ₊₃ is obtained thereby.

At step S306, the control device 60 computes a reward corresponding to the predicted state series sₜ₊₁, sₜ₊₂, sₜ₊₃ generated at step S305 according to a predetermined computation equation.

At step S307, the control device 60 determines whether or not the reward computed at step S306 satisfies a defined condition. Cases in which the defined condition is satisfied include, for example, when the reward has exceeded a defined value, when a loop of the processing of step S304 to step S307 has been executed a defined number of times, or the like. The defined number of times is set, for example, to 10 times, 100 times, 1000 times, or the like.

Processing transitions to step S308 when the reward has satisfied the defined condition, and processing transitions to step S304 when the reward has not satisfied the defined condition.

At step S308, the control device 60 generates a predicted command series based on the reward corresponding to the predicted state series of the robot 10 as computed at step S306. Note that the predicted command series may be the command series itself when the reward has satisfied the defined condition, may be predicted from a history of change in reward corresponding to changes in the command series, and furthermore may be a command series predicted as being able to maximize the reward. The first command at of the generated predicted command series is output to the robot 10.

The processing of step S301 to step S308 is repeated for each control period in this manner.

### Control Processing 2

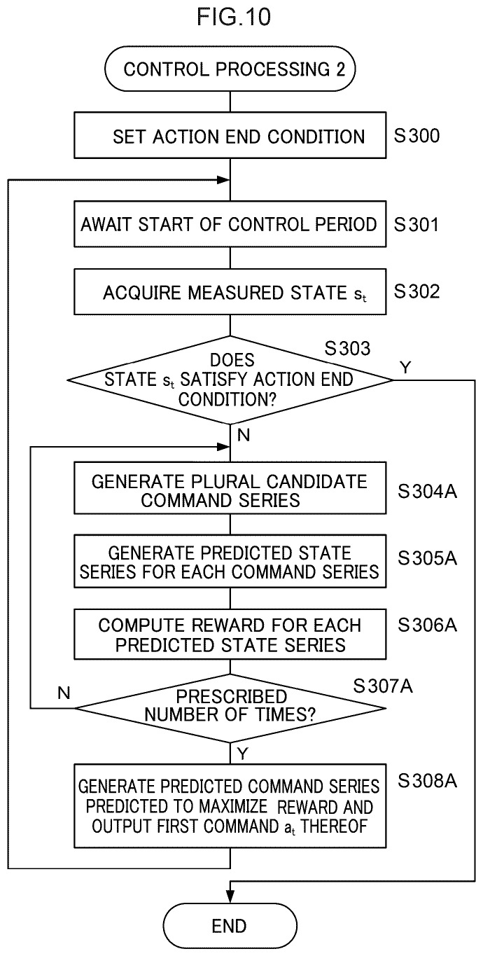

FIG. 10 is a flowchart illustrating a flow of control processing 2 executed by the control device 60 as another example of control processing. Note that the same reference numerals will be appended to steps that perform processing the same as FIG. 9, and detailed explanation thereof will be omitted.

As illustrated in FIG. 10, the processing of step S304A to step S308A differs from the processing illustrated in FIG. 9.

At step S304A, the control device 60 generates a batch of plural candidate command series for the robot 10. A cross-entropy method (CEM) may be employed, for example, to generate the plural candidate command series, however, there is no limitation thereto.

When using a CEM, plural (for example 300) candidate command series aₜ, aₜ₊₁, aₜ₊₂ are generated at random for the first time of the loop. From the second loop onward, plural (for example 30) command series corresponding to predetermined upper rank rewards are selected from out of the rewards computed by the processing of the previous cycle, and plural (for example 300) new candidate command series are generated according to a distribution (average, variance) of the selected command series.

At step S305A, the control device 60 generates a predicted state series for each of the command series generated at step S304A. The processing to generate the predicted state series corresponding to each of the command series is processing similar to that of step S305 of FIG. 9.

At step S306A, the control device 60 computes a reward for each of the predicted state series generated at step S305A. The processing to compute the reward for each of the predicted state series is processing similar to that of step S306.

At step S307A, the control device 60 determines whether or not the processing of step S304A to S306A has been executed a prescribed number of times. The prescribed number of times may, for example, be 10 times or the like, and may be freely set as one or more times.

At step S308A, the control device 60 generates a predicted command series predicted to maximize the reward based the rewards for each of the predicted state series computed at step S306A. For example, a relationship equation is computed to express a correspondence relationship between a command series aₜ, aₜ₊₁, aₜ₊₂ and rewards of a predicted state series sₜ₊₁, sₜ₊₂, sₜ₊₃ obtained from this command series aₜ, aₜ₊₁, aₜ₊₂, and then a predicted command series at, aₜ₊₁, aₜ₊₂ corresponding to the maximum reward on a curve expressing the computed relationship equation is generated, and the first command at therefrom is output.

However, it takes time just to execute the processing illustrated in FIG. 9 or FIG. 10 from when the state sₜ was acquired at step S302 until when the command action at is determined and output. “The dynamics models f are models that are input with a state sₜ of the robot 10 and a command action at commanded of the robot 10 at the state sₜ, and that output a next state sₜ₊₁ after the robot 10 has performed the command action aₜ” has been described above, however although theoretically the state sₜ and the command action at are values at the same time, in practice processing time to compute the command action at using the state sₜ occurs unavoidably. The expression “the command action at commanded of the robot 10 at state sₜ” does not exclude cases in which such processing time occurs. In order to get the actual control action to approach the theoretical action, the length of the control period is preferably sufficiently larger than this processing time (for example 10 times or greater).

Note that the above exemplary embodiments are merely exemplary to describe configuration examples of the present disclosure. The present disclosure is not limited to the specific embodiments described above, and various modifications may be made thereto within a range of the technical possibilities thereof.

Although in the above examples an example has been described of a case in which the cycle of actions executed by the robot 10 is the juggling action, the cycle of actions executed by the robot 10 may be any freely selected action.

Note that the training processing and the control processing executed in the above exemplary embodiments by a CPU reading software (programs), the processing may be executed by various processors other than a CPU. Examples of such processors include programmable logic devices (PLD) that allow circuit configuration to be modified post-manufacture, such as a field-programmable gate array (FPGA), and dedicated electric circuits, these being processors including a circuit configuration custom-designed to execute specific processing, such as an application specific integrated circuit (ASIC). Moreover the training processing and the control processing may be executed by any one of these various types of processor, or may be executed by a combination of two or more of the same type or different types of processor (such as plural FPGAs, or a combination of a CPU and an FPGA). Moreover, the hardware structure of these various types of processors is more specifically an electric circuit combining circuit elements such as semiconductor elements.

Moreover, although explanation has been given in each of the above exemplary embodiments of a mode in which the training program and the control program are pre-stored (installed) on the storage 40D or the ROM 40B, there is no limitation thereto. The programs may be provided in a format recorded on a recording medium such as a compact disk read only memory (CD-ROM), digital versatile disk read only memory (DVD-ROM), universal serial bus (USB) memory, or the like. The programs may also be provided downloaded from an external device over a network.

Note that the entirety of the disclosure of Japanese Patent Application No. 2021-109158 is incorporated by reference in the present specification. Moreover, all publications, patent applications and technical standards mentioned in the present specification are incorporated by reference in the present specification to the same extent as if each individual publication, patent application, or technical standard was specifically and individually indicated to be incorporated by reference.

1. A training and control device, comprising:
a state transition data acquisition section that acquires a plurality of state transition data obtained by causing a control target to perform a predetermined cycle of actions and configured including a state of the control target, a command action commanded of the control target at the state, and a next state after the control target has performed the command action;
a dynamics model generation section that generates a plurality of dynamics models input with the state and the command action and outputting the next state, with each of the dynamics models conforming to a set of state transition data configured from some of the acquired plurality of the state transition data, and the plurality of dynamics models conforming to mutually different sets of the state transition data;
an appending section that appends the state transition data contained in a set of the state transition data conforming to a generated dynamics model with a label to identify the generated dynamics model;
a training section that uses the state transition data appended with the label as training data to train a switching model for designating a dynamics model, among the plurality of dynamics models, which corresponds to the state of the control target and the command action which have been input;
a state acquisition section that acquires a state of the control target;
a candidate command series generation section that generates a plurality of candidate command series for the control target;
a designation section that designates a dynamics model applicable to each command and each state corresponding to the command by executing the switching model input with each command contained in a candidate command series and with a state corresponding to each command;
a predicted state series generation section that, for each candidate command series, uses the dynamics model designated as corresponding to the respective commands contained in the candidate command series to generate a predicted state series;
a computation section that computes a reward for each predicted state series;
a predicted command series generation section that generates a predicted command series predicted to maximize the reward;
an output section that outputs a first command contained in the generated predicted command series; and
an execution control section that controls action of the control target by repeating a cycle of actions of the state acquisition section, the candidate command series generation section, the designation section, the predicted state series generation section, the computation section, the predicted command series generation section, and the output section.

2. The training and control device of claim 1, wherein when generating a single dynamics model among the plurality of dynamics models, the dynamics model generation section:
generates a candidate for the dynamics model using all of the state transition data usable for generating the dynamics model, and then computes an error between the next state obtained when the state of the control target and the command action are input to the generated candidate dynamics model and the next state contained in the state transition data including the state and the command action; and
generates the dynamics model such that the computed error is a predetermined threshold value or lower by repeatedly generating the candidate dynamics model while removing the state transition data for which the error is a maximum.

3. The training and control device of claim 2, wherein, for each generating of a single dynamics model among the plurality of dynamics models, the dynamics model generation section treats the state transition data that remained not removed in a process to generate the dynamics model as being unusable for subsequent generating of the dynamics model, and generates a next of the dynamics models.

4. The training and control device of claim 2, wherein, at a predetermined frequency, the dynamics model generation section takes the state transition data selected at random among the state transition data removed as having the maximum error and returns the state transition data to the state transition data used for generating the dynamics model, and then generates the dynamics model.

5. The training and control device of claim 1, wherein:
the candidate command series generation section generates a single candidate for the command series;
the predicted state series generation section generates the predicted state series corresponding to the candidate command series generated by the candidate command series generation section;
the computation section computes a reward of the predicted state series generated by the predicted state series generation section; and
the predicted command series generation section generates a predicted command series for which the reward is predicted to be maximized by performing updating one or more times of the candidate command series such that the reward increases by causing a cycle of actions of the candidate command series generation section, the designation section, the predicted state series generation section, and the computation section to be executed a plurality of times.

6. The training and control device of claim 1, wherein:
the candidate command series generation section generates a batch of a plurality of candidates of the command series;
the predicted state series generation section generates the predicted state series from each of the plurality of candidates of the command series;
the computation section computes a reward for each of the predicted state series; and
the predicted command series generation section generates a predicted command series predicted to maximize the reward based on the reward for each of the predicted state series.

7. The training and control device of claim 6, wherein:
the candidate command series generation section causes processing of a cycle from processing for batch-generating the plurality of candidates of the command series until processing to compute the reward to be executed repeatedly a plurality of times; and
in processing of the cycle from a second time onward, the candidate command series generation section selects the plurality of candidates of the command series corresponding to predetermined upper rank rewards among rewards computed in processing of a previous cycle, and generates a new plurality of candidates of the command series based on a distribution of a selected plurality of candidates of the command series.

8. A training device, comprising:
a state transition data acquisition section that acquires a plurality of state transition data obtained by causing a control target to perform a predetermined cycle of actions and configured including a state of the control target, a command action commanded of the control target at the state, and a next state after the control target has performed the command action;
a dynamics model generation section that generates a plurality of dynamics models input with the state and the command action and outputting the next state, with each of the dynamics models conforming to a set of state transition data configured from some of the acquired plurality of the state transition data, and the plurality of dynamics models conforming to mutually different sets of the state transition data;
an appending section that appends the state transition data contained in a set of the state transition data conforming to a generated dynamics model with a label to identify the generated dynamics model; and
a training section that uses the state transition data appended with the label as training data to train a switching model for designating a dynamics model, among the plurality of dynamics models, which corresponds to the state of the control target and the command action which have been input.

9. A control device, comprising:
a state acquisition section that acquires a state of a control target;
a candidate command series generation section that generates a plurality of candidate command series for the control target;
a designation section that, by executing a switching model that is input with each command contained in each candidate command series and with a state corresponding to each command and that has been trained by the training device of claim 8, designates a dynamics model applicable to each command and each state corresponding to the command among the dynamics models generated by the training device;
a predicted state series generation section that, for each candidate command series, uses the dynamics model designated as corresponding to the respective commands contained in the candidate command series to generate a predicted state series;
a computation section that computes a reward for each predicted state series;
a predicted command series generation section that generates a predicted command series predicted to maximize the reward;
an output section that outputs a first command contained in the generated predicted command series; and
an execution control section that controls action of the control target by repeating a cycle of actions of the state acquisition section, the candidate command series generation section, the designation section, the predicted state series generation section, the computation section, the predicted command series generation section, and the output section.

10. A training and control method of processing executed by a computer, the processing comprising:
a state transition data acquisition step that acquires a plurality of state transition data obtained by causing a control target to perform a predetermined cycle of actions and configured including a state of the control target, a command action commanded of the control target at the state, and a next state after the control target has performed the command action;
a dynamics model generation step that generates a plurality of dynamics models input with the state and the command action and outputting the next state, with each of the dynamics models conforming to a set of state transition data configured from some of the acquired plurality of the state transition data, and the plurality of dynamics models conforming to mutually different sets of the state transition data;
an appending step that appends the state transition data contained in a set of the state transition data conforming to a generated dynamics model with a label to identify the generated dynamics model;
a training step that uses the state transition data appended with the label as training data to train a switching model for designating a dynamics model, among the plurality of dynamics models, which corresponds to the state of the control target and the command action which have been input;
a state acquisition step that acquires a state of the control target;
a candidate command series generation step that generates a plurality of candidate command series for the control target;
a designation step that designates a dynamics model applicable to each command and each state corresponding to the command by executing the switching model input with each command contained in a candidate command series and with a state corresponding to each command;
a predicted state series generation step that, for each candidate command series, uses the dynamics model designated as corresponding to the respective commands contained in the candidate command series to generate a predicted state series;
a computation step that computes a reward for each predicted state series;
a predicted command series generation step that generates a predicted command series predicted to maximize the reward;
an output step that outputs a first command contained in the generated predicted command series; and
an execution control step that controls action of the control target by repeating a cycle of actions of the state acquisition step, the candidate command series generation step, the designation step, the predicted state series generation step, the computation step, the predicted command series generation step, and the output step.

11. A training method of processing executed by a computer, the processing comprising:
a state transition data acquisition step that acquires a plurality of state transition data obtained by causing a control target to perform a predetermined cycle of actions and configured including a state of the control target, a command action commanded of the control target at the state, and a next state after the control target has performed the command action;
a dynamics model generation step that generates a plurality of dynamics models input with the state and the command action and outputting the next state, with each of the dynamics models conforming to a set of state transition data configured from some of the acquired plurality of the state transition data, and the plurality of dynamics models conforming to mutually different sets of the state transition data;
an appending step that appends the state transition data contained in a set of the state transition data conforming to a generated dynamics model with a label to identify the generated dynamics model; and
a training step that uses the state transition data appended with the label as training data to train a switching model for designating a dynamics model, among the plurality of dynamics models, which corresponds to the state of the control target and the command action which have been input.

12. A control method of processing executed by a computer, the processing comprising:
a state acquisition step that acquires a state of a control target;
a candidate command series generation step that generates a plurality of candidate command series for the control target;
a designation step that, by executing a switching model that is input with each command contained in each candidate command series and with a state corresponding to each command and that has been trained by the training method of claim 11, designates a dynamics model applicable to each command and each state corresponding to the command among the dynamics models generated by the training method;
a predicted state series generation step that, for each candidate command series, uses the dynamics model designated as corresponding to the respective commands contained in the candidate command series to generate a predicted state series;
a computation step that computes a reward for each predicted state series;
a predicted command series generation step that generates a predicted command series predicted to maximize the reward;
an output step that outputs a first command contained in the generated predicted command series; and
an execution control step that controls action of the control target by repeating a cycle of actions of the state acquisition step, the candidate command series generation step, the designation step, the predicted state series generation step, the computation step, the predicted command series generation step, and the output step.

13. A non-transitory recording medium storing a training and control program that causes a computer to execute processing, the processing comprising:
a state transition data acquisition step that acquires a plurality of state transition data obtained by causing a control target to perform a predetermined cycle of actions and configured including a state of the control target, a command action commanded of the control target at the state, and a next state after the control target has performed the command action;
a dynamics model generation step that generates a plurality of dynamics models input with the state and the command action and outputting the next state, with each of the dynamics models conforming to a set of state transition data configured from some of the acquired plurality of the state transition data, and the plurality of dynamics models conforming to mutually different sets of the state transition data;
an appending step that appends the state transition data contained in a set of the state transition data conforming to a generated dynamics model with a label to identify the generated dynamics model;
a training step that uses the state transition data appended with the label as training data to train a switching model for designating a dynamics model, among the plurality of dynamics models, which corresponds to the state of the control target and the command action which have been input;
a state acquisition step that acquires a state of the control target;
a candidate command series generation step that generates a plurality of candidate command series for the control target;
a designation step that designates a dynamics model applicable to each command and each state corresponding to the command by executing the switching model input with each command contained in a candidate command series and with a state corresponding to each command;
a predicted state series generation step that, for each candidate command series, uses the dynamics model designated as corresponding to the respective commands contained in the candidate command series to generate a predicted state series;
a computation step that computes a reward for each predicted state series;
a predicted command series generation step that generates a predicted command series predicted to maximize the reward;
an output step that outputs a first command contained in the generated predicted command series; and
an execution control step that controls action of the control target by repeating a cycle of actions of the state acquisition step, the candidate command series generation step, the designation step, the predicted state series generation step, the computation step, the predicted command series generation step, and the output step.

14. A non-transitory recording medium storing a training program that causes a computer to execute processing, the processing comprising:
a state transition data acquisition step that acquires a plurality of state transition data obtained by causing a control target to perform a predetermined cycle of actions and configured including a state of the control target, a command action commanded of the control target at the state, and a next state after the control target has performed the command action;
a dynamics model generation step that generates a plurality of dynamics models input with the state and the command action and outputting the next state, with each of the dynamics models conforming to a set of state transition data configured from some of the acquired plurality of the state transition data, and the plurality of dynamics models conforming to mutually different sets of the state transition data;
an appending step that appends the state transition data contained in a set of the state transition data conforming to a generated dynamics model with a label to identify the generated dynamics model; and
a training step that uses the state transition data appended with the label as training data to train a switching model for designating a dynamics model, among plurality of dynamics models, which corresponds to the state of the control target and the command action which have been input.

15. A non-transitory recording medium storing a control program that causes a computer to execute processing, the processing comprising:
a state acquisition step that acquires a state of a control target;
a candidate command series generation step that generates a plurality of candidate command series for the control target;
a designation step that, by executing a switching model that is input with each command contained in each candidate command series and with a state corresponding to each command and that has been trained by the training program of claim 14, designates a dynamics model applicable to each command and each state corresponding to the command among the dynamics models generated by the training program;
a predicted state series generation step that, for each candidate command series, uses the dynamics model designated as corresponding to the respective commands contained in the candidate command series to generate a predicted state series;
a computation step that computes a reward for each predicted state series;
a predicted command series generation step that generates a predicted command series predicted to maximize the reward;
an output step that outputs a first command contained in the generated predicted command series; and
an execution control step that controls action of the control target by repeating a cycle of actions of the state acquisition step, the candidate command series generation step, the designation step, the predicted state series generation step, the computation step, the predicted command series generation step, and the output step.
